(19) United States
(12) Patent Application Publication
(10) Pub. No.: US 2022/0005675 A1
(43) Pub. Date: Jan. 6, 2022

(54) DUAL-PHASE COOLING IN SEMICONDUCTOR MANUFACTURING

(71) Applicant: Lam Research Corporation, Fremont, CA (US)

(72) Inventors: Anthony de la Llera, Fremont, CA (US); Adam Mace, Morgan Hill, CA (US)

(21) Appl. No.: 17/293,002

(22) PCT Filed: Nov. 19, 2019
(86) PCT No.: PCT/US2019/062296

§ 371 Date: May 11, 2021

Related U.S. Application Data
(60) Provisional application No. 62/770,130, filed on Nov. 20, 2018.

(51) Int. Cl. H01J 37/32

(52) U.S. Cl. CPC H01J 37/32522; H01J 2237/332; H01J 2237/334; H01J 2237/002

(57) ABSTRACT

In some examples, a substrate processing system comprises a processing chamber, a dual-phase cooling system, and a back-pressure regulator which regulates the pressure of the dual-phase coolant. The dual-phase cooling system regulates the temperature of the processing chamber or a first component thereof. The dual-phase cooling system includes a cooling loop in thermal communication with the processing chamber or the component. The cooling loop contains a dual-phase coolant in fluid communication with a heat exchanger. The processing chamber or the first component includes a top plate or a cool plate comprising one or more e passageways forming part of the cooling loop.

### CLAIM OF PRIORITY

This application claims the benefit of priority to U.S. Patent Application No. 62/770,130, to de la Llera et al, entitled “Dual-Phase Cooling In Semiconductor Manufacturing” filed on Nov. 20, 2018, which is incorporated by reference herein in its entirety.

### FIELD

The present disclosure relates to dual-phase cooling in semiconductor manufacturing, and more particularly to systems and methods for dual-phase cooling in high-powered etch modules for manufacturing semiconductor wafers.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Currently, dielectric chambers increasingly use higher amounts of RF power to process a semiconductor wafer. This creates significant challenges in controlling the temperature of the chamber components. Materials currently being used have temperature limits that do not allow for elevated levels of power to be used efficiently.

### SUMMARY

In some examples, dual-phase cooling is generally provided in semiconductor manufacturing components described below. Some examples circulate coolant through a processing or cooling plate, (e.g. a top plate in a dielectric processing chamber), or through a plate assembly (e.g. a dielectric etch top plate assembly), allowing partial evaporation of the coolant within the plate or plate assembly. Some examples thereby leverage the latent heat of vaporization needed for a liquid-vapor phase change of the coolant to cool the plate or assembly. The heat is released at an external condenser. Dual-phase coolant may be used instead of conventional process cooling water (PCW).

Some examples utilize dual-phase cooling in an electrostatic chuck (ESC) i.e. in a lower electrode instead of or in conjunction with an upper electrode, such as a plate of plate assembly as described above.

In some examples, the dual-phase coolant is retained within a cooling system at a system pressure just below saturation (or boiling) pressure, or saturation temperature. The pressure-dependent temperature at which dual-phase coolant phase-change is desired to occur can be controlled by adjusting the system pressure. A degree of cooling of the top plate or assembly can be controlled accordingly. The plate or assembly may be held at constant temperature. The dual-phase coolant itself may be heated or conditioned for use in a given process by a dedicated coolant heater.

In some examples, a design of the cooling system, plate and/or plate assembly may be configured to fit within existing manufacturing footprints. Process components not requiring special cooling may be isolated by thermal breaks from process plates or assemblies for efficiency savings and control. For example, components may be separated (or alternatively combined) in a given assembly to provide thermal breaks or more optimum cooling/heating profiles and/or functionality, for example a separate Gas Distribution Plate (GDP) and cooling plate, or other component provided within a top plate assembly, or more generally in a wafer processing chamber.

Some examples may include silicon mounted directly to a cooling plate, for example using cams, to eliminate the need for multiple parts in a stack (top plate assembly). In some examples, a cooling assembly or plate includes embedded cooling and/or gas paths, and may include a plurality of gas zones, for example. Some example top plate or assembly designs may be configured to incorporate or provide specific heat and/or cooling gradients, or coolant type, temperature and flow, from component to component, or across a stack of components.

Modular component design may be employed with, for example, key components located in a single enclosure for ease of operability. Some examples include brazing of disparate components together to integrate system functionality while providing fewer parts and/or seals.

In some examples, a dual-phase coolant and operational parameters, plate and assembly designs may be selected and designed to suit customer requirements.

In some examples, quick-disconnect convenience may be incorporated within a dual-phase cooling system, particularly for larger process components. Quick-disconnect points may be provided in the coolant or other supply lines between system components and processing units, for examples for easier servicing of components.

In some examples, post phase-change vapor circulation allows for continued heat exchange. Components within the cooling system are adapted or configured to retain circulation of vapor, even after phase-change. Some examples do not require use of special pumps and rely on coolant pressure gradients alone. Multiple cooling plates may be employed within one cooling system.

In some hybrid PCW/dual-phase coolant examples, PCW is used to transfer heat out of the cooling system at the condenser. In one example, PCW is heated to ˜30 C to lower the energy needed to maintain a consistent coolant temperature for tools connected to PCW with a large temperature range. Performance will therefore be consistent from tool to tool. A point of use heater is used to raise the temperature of the working fluid during idle states in the processing. When wafer processing commences, the elevated temperature PCW at the outlet can be mixed with incoming cooler PCW to save energy, and reduce the need for PCW, dual-phase coolant, or process heaters.

Some examples may derive energy savings by mixing some of the condenser cooling output fluid to heat the cooling input fluid. In some examples, the condenser is located in the top plate, other examples include the condenser in a sub fabrication. A location of a condenser within a cooling system may depend on the sizing of system components.

Further areas of applicability of the present disclosure will become apparent from the detailed description, the claims, and the drawings. The detailed description and specific examples are intended for purposes of illustration only and are not intended to limit the scope of the disclosure.

### DESCRIPTION OF THE DRAWINGS

Some embodiments are illustrated by way of example and not limitation in the views of the accompanying drawings:

FIGS. 1A-1B are schematic diagrams of aspects of a cooling system including a PCW loop, in accordance with example embodiments.

FIGS. 2-4 are schematic sectional views of top plate assemblies, in accordance with example embodiments.

FIG. 5 is a block diagram illustrating an example of a machine upon which one or more example embodiments may be implemented, or by which one or more example embodiments may be controlled.

### DESCRIPTION

The description that follows includes systems, methods, techniques, instruction sequences, and computing machine program products that embody illustrative embodiments of the present invention. In the following description, for purposes of explanation, numerous specific details are set forth in order to provide a thorough understanding of example embodiments. It will be evident, however, to one skilled in the art, that the present embodiments may be practiced without these specific details.

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice applies to any data as described below and in the drawings that form a part of this document: Copyright Lam Research Corporation, 2018. All Rights Reserved.

By way of general background, semiconductors usually start as a wafer-thin slice of a purified semiconductor material. Usually these wafers are produced by heating the material, molding it, and processing it to cut and grind it into small, smooth wafers. In a deposition phase, the prepared wafers are cleaned, heated and exposed to pure oxygen within a diffusion furnace. This results in a reaction that produces a uniform film of silicon dioxide on the surface of the wafer. In a masking phase (also called photolithography or photo-masking), this process protects one area of the wafer while another is worked on. After applying a light-sensitive film to one part of the wafer, an intense light is then projected through a mask onto it, exposing the film with the mask pattern. In an etching phase, manufacturers bake the wafer to harden the remaining film pattern, and then expose it to a chemical solution to eat away the areas not covered by the hardened film. After this step, the film is removed, and the wafer is inspected to ensure proper image transfer. Doping, deposition, and plating phases may follow in the semiconductor manufacturing process.

As discussed further above, component materials currently being used in an etching phases (for example) have temperature limits that don't allow for elevated levels of RF power to be used efficiently. In some examples, the affected parts of a processing chamber may include a dielectric etch top plate assembly. This assembly includes upper electrodes, metal plates on the outside of the assembly, as well as gaskets and O-rings that may be needed for operation.

In conventional designs, the top plate is liquid cooled using process cooling water (PCW) or other coolant media (fluorinert). Using these methods there are limits to the amount of power that can be dissipated through the coolant. These limits may be based on flow rates, coolant properties, and chiller/temperature control unit (TCU) size. Some examples utilize a stack of plates and various plate interface materials to transfer heat to the cooling fluid. Within the stack, the heaters are positioned against the cooling plate. This may cause a majority of the heat generated by the heaters to go directly to the coolant even before it has had an opportunity to heat the area where temperature control is needed (electrode).

Typically, there are two modes in which heat is added to a wafer processing system. First, heat is added during wafer processing when RF power is introduced into the system. The heat input begins at the bottom of the assembly through the upper electrode and then transfers through the stack of plates until it reaches the coolant. As the heat is transferred across interfaces and components, there is a temperature increase. This temperature increase reaches a level that can destroy the assembly components if sufficient RF power is introduced into the system.

A second way heat may be introduced into a wafer processing system is with the use of the heaters during an “idle” state. During the idle state, one aim is to keep the electrodes and backing plates at the same temperature as they were when wafers are being processed during the phases described above. For this concept to work, the heaters should be large enough to overcome the cooling capability of the cooling plate without incurring a thermal runaway situation. As a result, the heaters used in a conventional system may be very large and powerful and require significant levels of power to achieve the desired aim of maintaining the top plate at a desired temperature. Current methods are now reaching the cooling limits of conventional system components and component materials.

In some current examples, this issue is addressed by upgrading from a single-phase cooling system (liquid cooled) to a pumped dual-phase cooling system. In some examples, this approach allows a constant temperature to be held even at extremely high levels of heat input into the cooling plate. In some examples, coolant media enters a top plate or assembly of a processing chamber in a condition at or near the saturation temperature or boiling point of the media. As the media is heated by the heat extracted from the top plate or assembly, the media begins to boil and evaporate. The energy used to change the media state from liquid to gas is transferred externally when the evaporated material condenses back into liquid state.

In some configurations, this method allows more heat to be transferred out of a wafer processing system than if the coolant media were to remain in a liquid state. In addition, because the media is at or near saturation temperature, it holds a substantially uniform state while traveling through a top plate or assembly cooling channel or plenum thereby assisting in maintaining a substantially uniform temperature across the plate. By comparison, the temperature of the coolant in a conventional liquid-cooled system typically increases with time spent in top plate or assembly cooling channels making it difficult to provide and maintain a uniform temperature across the top plate. This phenomenon is especially noticeable at higher processing powers.

In some present examples, temperature set points are controlled by controlling the pressure in the cooling channels within the top plate or assembly (the evaporator). As pressure increases, the saturation temperature for the fluid increases. Conversely, as the pressure decreases, the saturation temperature decreases. An appropriate media may be selected for a given temperature range. In some examples, this method require some heating of the media. This may be accomplished by using a heater embedded, for example, in a top plate or assembly or provided at a point of use. In either case, the amount of energy needed to heat the media may be much smaller than (even a small fraction of) the energy consumed in a single phase liquid cooled system. In some examples, no heater is provided on the top plate or assembly and instead the media is heated as it enters the cooling system.

Some examples include a condenser circuit in which PCW is used to transfer the heat out of the system. For this to occur, the PCW is heated to maintain a consistent inlet temperature, irrespective of the supply temperature, to lower the energy needed by the associated processing facility to dissipate the heat generated by the cooling system. A point of use heater can be used to raise the temperature of the PCW during the idle state discussed above. When the top plate or assembly begins to process wafers, the elevated temperature PCW at the outlet can be mixed with incoming cooler PCW to save energy. In some examples, the PCW heater would not need to supply significant energy to maintain the higher PCW temperature.

In some examples, a plate stack in a top plate assembly may be utilized. In conventional assemblies, a stack may include coolant, a cooling plate, heaters, a gas distribution plate (GDP) or back plate, and electrodes. In some conventional examples, a gasket material is provided at an interface between each part. In use, the assembly temperature increases from the cooling plate to the electrodes through every part thickness and every gasket. In current examples on the other hand, a stack may include a top plate, an insulator, a gas distribution plate (GDP), a chill plate, and electrodes. In one aspect, a desired aim is to isolate the cooling plate from the gas distribution plate or the gas distribution plate from the top plate. This arrangement may leave only a smaller mass requiring temperature control. Further, the temperature increase in use would only occur from the electrode to cooling plate. Generally, examples arrangement generate significantly less temperature change with fewer interfaces between and thicknesses of components in a stack.

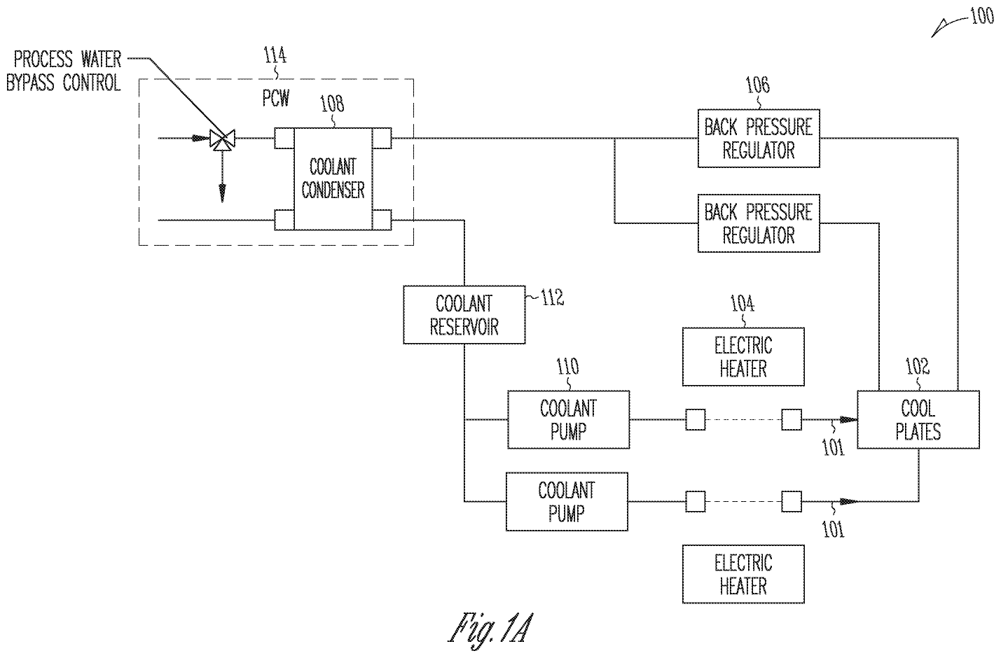

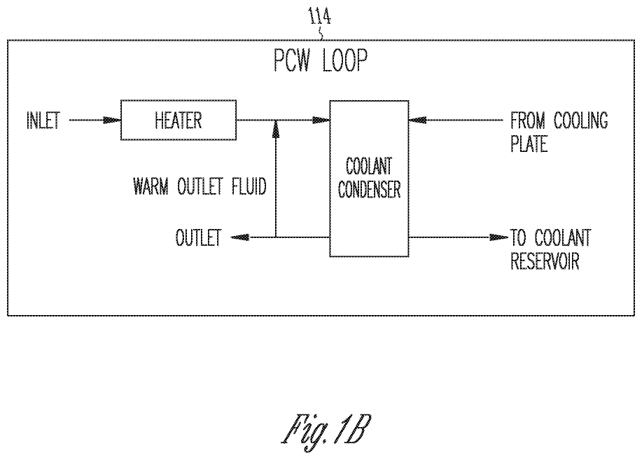

FIG. 1A includes for general reference purposes a layout of an example cooling system 100. In the illustrated cooling system 100, heat energy is transferred into a dual-phase cooling medium (such as a cooling fluid) during a phase change (liquid to gas) then removes the energy when the fluid changes state again (gas to liquid). Cooling fluid 101 enters a cooling plate 102 near saturation temperature. One or more point-of-use heaters 104 heat the cooling fluid before it enters the cooling plate 102. One or more cooling plates may be provided and jointly cooled by the methods described herein. Back pressure regulators 106 control the pressure within the coolant loop thereby controlling the saturation temperature. Some of the cooling fluid boils and evaporates as it flows through the channel. This draws heat from the cooling system and results in cooling of the cooling plate and/or other thermally-connected components in the cooling system. The cooling fluid returns to a liquid phase at a coolant condenser 108. The system also includes one or more coolant pumps 110 and a coolant reservoir 110. A PCW loop 114 may be provided in conjunction with the condenser 108. An enlarged view of the PCW loop 114 is shown in FIG. 1B with components and flow directions as shown.

Some example systems 100 use PCW as a primary coolant media for the condenser 108. In one example arrangement 116, condenser outlet fluid is mixed with condenser inlet fluid to elevate the temperature of the PCW to greater than 20° C. Mixing some of the condenser cooling output fluid to heat the cooling input fluid may result in energy savings. In another example, the PCW flow is adjusted as RF power input changes. For example, a low PCW flow at low RF power inputs, and high PCW flow at high RF power inputs.

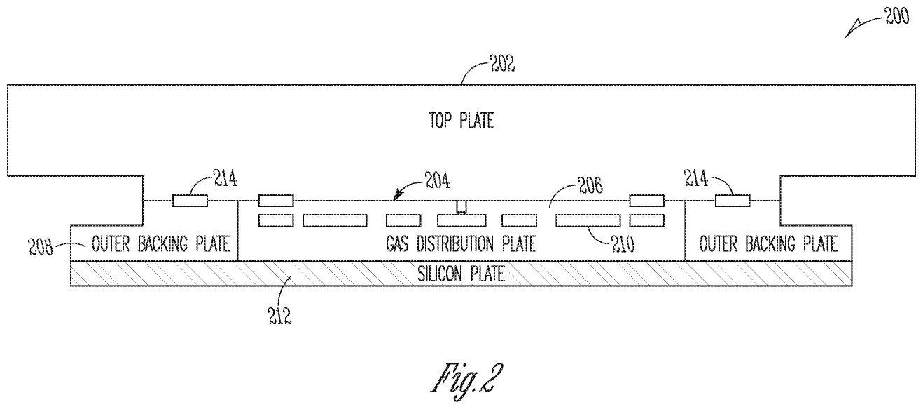

FIG. 2 shows a sectional view of a top plate assembly or stack 200. The assembly 200 includes a top plate 202, a cooling plate 204 that includes a gas distribution plate (GDP) 206, and an outer backing plate (OBP) 208. In the illustrated example, the GDP 206 forms an integral part of the cooling plate 204 (i.e. a unitary structure). The OBP may also form an integral part but is shown here as a separate component. The GDP 206 includes gas distribution channels 210 shown in schematic outline in a full or partial concentric ring pattern in FIG. 6. Other patterns are possible. In this example of a top plate assembly 200, a silicon plate 212 is provided directly adjacent a lower surface of the GDP 206/cooling plate 204. This arrangement can help to smooth temperature gradients and minimize a need for multiple parts or layers in the stack 200. Thermal breaks 214 may be provided between some or all the layers of the stack 200.

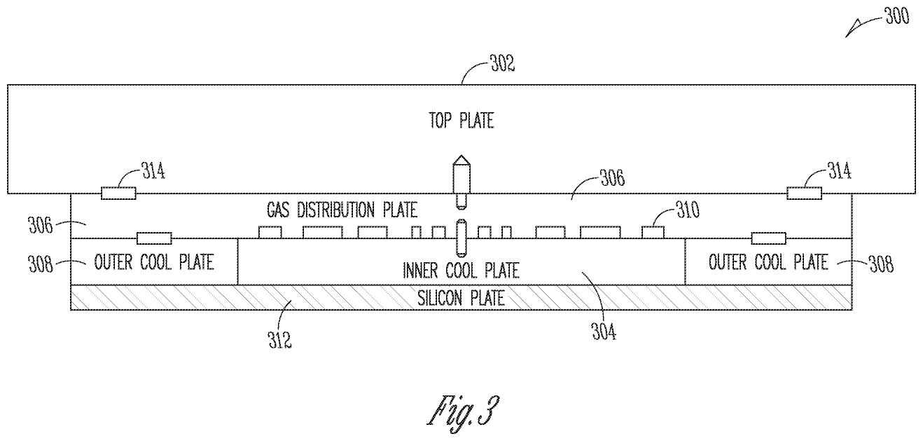

FIG. 3 shows a sectional view of another example of a top plate assembly or stack 300. The stack 300 includes a top plate 302, an inner cool plate 304, a GDP 306, an outer cool plate 308. Some examples may employ an open plenum design which may be easier to clean and anodize. The inclusion of multiple parts may make replacing damaged parts easier. The plates within the stack 300 are relatively smaller in size and more manageable to handle. The smaller cooling plates 304 and 308 have less mass to move thermally. The GDP 306 may include gas distribution channels or a gas plenum path 310. Thermal breaks to isolate the cool plates from the top plate may be provided between some or all the layers of the stack 300, for example at 314.

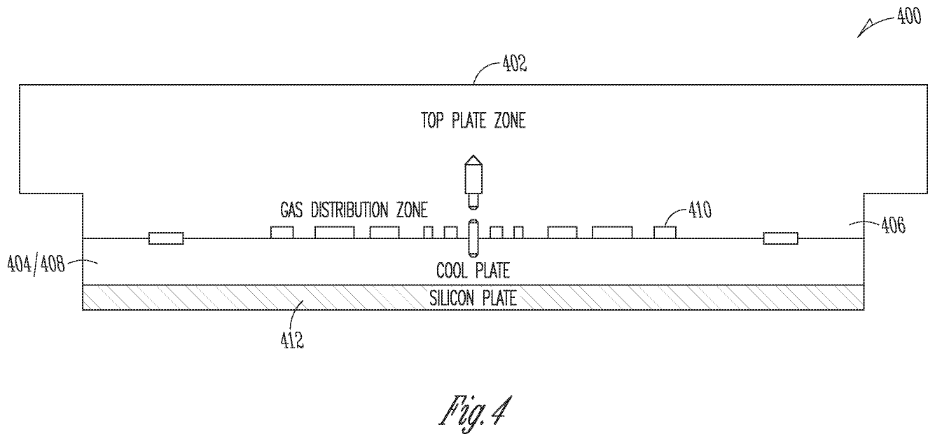

FIG. 4 shows a sectional view of another example of a top plate assembly or stack 400 formed as a one-piece part. The integrally formed components of the stack 400 may nevertheless generally function in the same or similar manner as the separate components of stack 200 or stack 300.

Dual-phase cooling systems and assemblies of the present disclosure may be used in conjunction with other components of a wafer processing system. For example, time-varying thermal loads may be central to semiconductor wafer processing, where heat generation necessarily occurs on a discrete basis (wafer to wafer). Spatially varying thermal loads are also common in etch process modules, where plasma's density and proximity to components are non-uniform. Also, it may be desirable for components of plasma processing chambers to be at certain temperatures during plasma processing and these components are not heated by the plasma until wafer processing begins. Circulating a hot liquid allows a first wafer to be processed without first wafer effects, but as plasma processing continues, the components are heated by the plasma such that the components need to be cooled to a target elevated temperature, as described in commonly-assigned US Published Patent Application No. 2008/0308228, hereby incorporated by reference in its entirety, or by using a dual-phase cooling method as described herein, or by a combination of such methods.

Some examples of dual-phase cooling systems may include a liquid cooled window, as described in commonly-assigned U.S. Pat. No. 8,970,114 B2, hereby incorporated by reference in its entirety.

Thus, some embodiments may include one or more of the following examples.

1. A substrate processing system, comprising: a processing chamber for processing a substrate, a dual-phase cooling system for regulating a temperature of the processing chamber or a first component thereof, the dual-phase cooling system including a cooling loop in thermal communication with the processing chamber or the component, the cooling loop containing a dual-phase coolant in fluid communication with a heat exchanger; the processing chamber or the first component including a top plate or a cool plate comprising one or more passageways forming part of the cooling loop and through which the dual-phase coolant can pass in a path to and from the heat exchanger; and a back-pressure regulator for regulating a pressure of the dual-phase coolant.

2. The substrate processing system of example 1, further comprising at least one heater to regulate a temperature of the dual-phase coolant prior to entry or passage of the dual-phase coolant through a section of the cooling loop.

3. The substrate processing system of example 1 or 2, wherein the pressure of the dual-phase coolant regulated by the back-pressure regulator is based on a saturation temperature of the dual-phase coolant or a temperature differential thereof.

4. The substrate processing system of any one of examples 1-3, wherein a temperature of the top plate or cool plate is regulated by the dual-phase cooling system, the regulated cool plate temperature based on a substrate deposition or substrate etch processing temperature.

5. The substrate processing system of any one of examples 1-4, wherein the processing chamber is powered by RF power and wherein the cool plate forms part of a lower electrode of the processing chamber.

6. The substrate processing system of any one of examples 1-5, wherein the processing chamber is powered by RF power and wherein the top plate forms part of an upper electrode of the processing chamber.

7. The substrate processing system of any one of examples 1-6, wherein a temperature of the top plate or cool plate is regulated by the dual-phase cooling system, the regulated cool plate temperature enabling partial evaporation of the dual-phase coolant within the top plate or cool plate.

8. The substrate processing system of any one of examples 1-7, wherein the first component is separated from a second component of the processing chamber by a thermal break.

9. The substrate processing system of any one of examples 1-8, wherein the top or cool plate includes a plurality of gas zones.

10. The substrate processing system of any one of examples 1-9, wherein the cooling loop includes a quick-disconnect connection.

11. The substrate processing system of any one of examples 1-10, further comprising a process cooling water (PCW) cooling loop.

12. The substrate processing system of any one of examples 1-11, wherein the dual-phase cooling loop can exchange heat with the PCW cooling loop.

13. The substrate processing system of any one of examples 1-12, wherein the top plate or cool plate is included in a stack assembly.

14. The substrate processing system of any one of examples 1-13, wherein the one or more passageways of the top plate or the cool plate include a full or partial concentric ring pattern.

15. The substrate processing system of anyone of examples 1-14, wherein the plurality of gas zones include a full or partial concentric ring pattern.

Some examples of this disclosure include methods. In an example, method of regulating processing temperature in a substrate processing system is provided. The method may be performed in association with a processing chamber or a component thereof. The method may comprise providing a dual-phase cooling system for regulating a temperature of the processing chamber or a component thereof, the dual-phase cooling system including a cooling loop in thermal communication with the processing chamber or the component; the processing chamber or the component including a top plate or a cool plate comprising one or more passageways forming part of the cooling loop and through which the dual-phase coolant can pass in a path to and from a heat exchanger; passing a dual-phase coolant through the cooling loop to and from the heat exchanger; and operating a back-pressure regulator for regulating a pressure of the dual-phase coolant.

Example methods may further include providing or performing any of the operations or components included in the examples 1-15 above, or as described elsewhere herein.

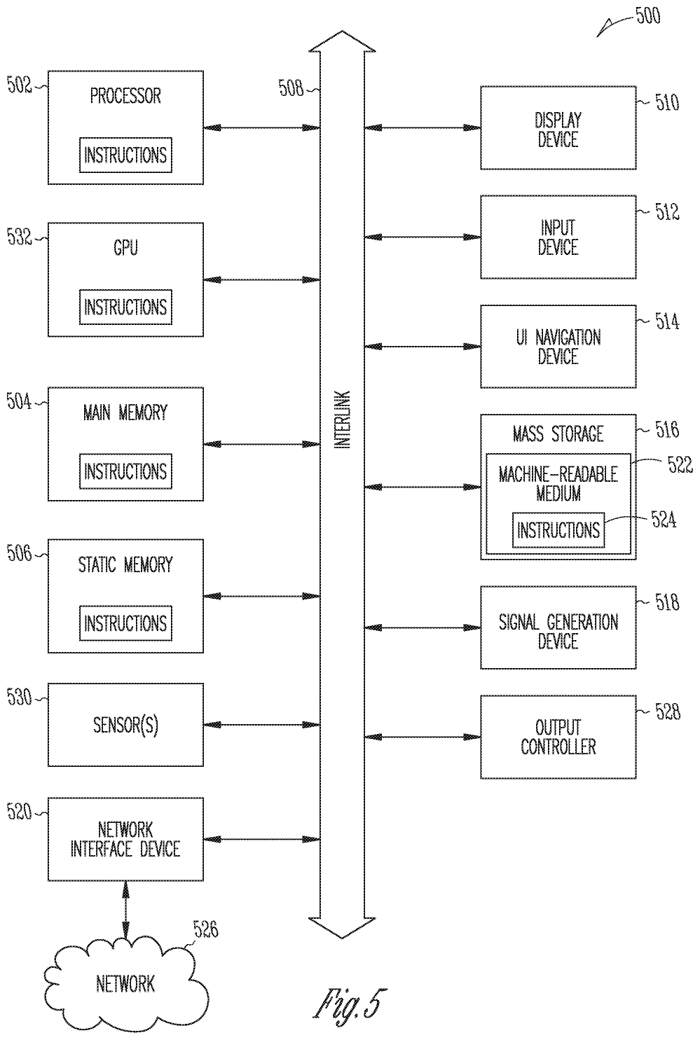

FIG. 5 is a block diagram illustrating an example of a machine 500 (such as a controller within a condenser circuit enclosure 802, or 902) by which one or more example process embodiments described herein may be controlled. In alternative embodiments, the machine 500 may operate as a standalone device or may be connected (e.g., networked) to other machines. In a networked deployment, the machine 500 may operate in the capacity of a server machine, a client machine, or both in server-client network environments. In an example, the machine 500 may act as a peer machine in a peer-to-peer (P2P) (or other distributed) network environment. Further, while only a single machine 500 is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations. In some examples, and referring to FIG. 5, a non-transitory machine-readable medium includes instructions 524 that, when read by a machine 500, cause the machine to control operations in methods comprising at least the non-limiting example operations summarized above.

Examples, as described herein, may include, or may operate by logic, a number of components or mechanisms. Circuitry is a collection of circuits implemented in tangible entities that include hardware (e.g., simple circuits, gates, logic, etc.). Circuitry membership may be flexible over time and underlying hardware variability. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, by moveable placement of invariant massed particles, etc.) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 500 may include a hardware processor 502 (e.g., a central processing unit (CPU), a hardware processor core, or any combination thereof), a graphics processing unit (GPU) 532, a main memory 504, and a static memory 506, some or all of which may communicate with each other via an interlink (e.g., bus) 508. The machine 500 may further include a display device 510, an alphanumeric input device 512 (e.g., a keyboard), and a user interface (UI) navigation device 514 (e.g., a mouse). In an example, the display device 510, alphanumeric input device 512, and UI navigation device 514 may be a touch screen display. The machine 500 may additionally include a mass storage device (e.g., drive unit) 516, a signal generation device 518 (e.g., a speaker), a network interface device 520, and one or more sensors 530, such as a Global Positioning System (GPS) sensor, compass, accelerometer, or another sensor. The machine 500 may include an output controller 528, such as a serial (e.g., universal serial bus (USB)), parallel, or other wired or wireless (e.g., infrared (IR), near field communication (NFC), etc.) connection to communicate with or control one or more peripheral devices (e.g., a printer, card reader, etc.).

The mass storage device 516 may include a machine-readable medium 522 on which is stored one or more sets of data structures or instructions 524 (e.g., software) embodying or utilized by any one or more of the techniques or functions described herein. The instructions 524 may as shown also reside, completely or at least partially, within the main memory 504, within the static memory 506, within the hardware processor 502, or within the GPU 532 during execution thereof by the machine 500. In an example, one or any combination of the hardware processor 502, the GPU 532, the main memory 504, the static memory 506, or the mass storage device 516 may constitute machine-readable media 522.

While the machine-readable medium 522 is illustrated as a single medium, the term “machine-readable medium” may include a single medium or multiple media (e.g., a centralized or distributed database, and/or associated caches and servers) configured to store the one or more instructions 524.

The term “machine-readable medium” may include any medium that can store, encode, or carry instructions 524 for execution by the machine 500 and that cause the machine 500 to perform any one or more of the techniques of the present disclosure, or that can store, encode, or carry data structures used by or associated with such instructions 524. Non-limiting machine-readable medium examples may include solid-state memories, and optical and magnetic media. In an example, a massed machine-readable medium comprises a machine-readable medium 522 with a plurality of particles having invariant (e.g., rest) mass. Accordingly, massed machine-readable media are not transitory propagating signals. Specific examples of massed machine-readable media may include non-volatile memory, such as semiconductor memory devices (e.g., electrically programmable read-only memory (EPROM), electrically erasable programmable read-only memory (EEPROM)) and flash memory devices; magnetic disks, such as internal hard disks and removable disks; magneto-optical disks; and CD-ROM and DVD-ROM disks. The instructions 524 may further be transmitted or received over a communications network 526 using a transmission medium via the network interface device 520.

Although an embodiment has been described with reference to specific example embodiments, it will be evident that various modifications and changes may be made to these embodiments without departing from the broader scope of the inventive subject matter. Accordingly, the specification and drawings are to be regarded in an illustrative rather than a restrictive sense. The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover all adaptations or variations of various embodiments. Combinations of the above embodiments, and other embodiments not specifically described herein, will be apparent to those of skill in the art upon reviewing the above description.

What is claimed is:

1. A substrate processing system, comprising:
a processing chamber for processing a substrate,
a dual-phase cooling system for regulating a temperature of the processing chamber or a first component thereof, the dual-phase cooling system including a cooling loop in thermal communication with the processing chamber or the component, the cooling loop containing a dual-phase coolant in fluid communication with a heat exchanger;
the processing chamber or the first component including a top plate or a cool plate comprising one or more passageways forming part of the cooling loop and through which the dual-phase coolant can pass in a path to and from the heat exchanger; and
a back-pressure regulator for regulating a pressure of the dual-phase coolant.

2. The substrate processing system of claim 1, further comprising at least one heater to regulate a temperature of the dual-phase coolant prior to entry or passage of the dual-phase coolant through a section of the cooling loop.

3. The substrate processing system of claim 1, wherein the pressure of the dual-phase coolant regulated by the back-pressure regulator is based on a saturation temperature of the dual-phase coolant or a temperature differential thereof.

4. The substrate processing system of claim 1, wherein a temperature of the top plate or cool plate is regulated by the dual-phase cooling system, the regulated cool plate temperature based on a substrate deposition or substrate etch processing temperature.

5. The substrate processing system of claim 1, wherein the processing chamber is powered by RF power and wherein the cool plate forms part of a lower electrode of the processing chamber.

6. The substrate processing system of claim 1, wherein the processing chamber is powered by RF power and wherein the top plate forms part of an upper electrode of the processing chamber.

7. The substrate processing system of claim 1, wherein a temperature of the top plate or cool plate is regulated by the dual-phase cooling system, the regulated cool plate temperature enabling partial evaporation of the dual-phase coolant within the top plate or cool plate.

8. The substrate processing system of claim 1, wherein the first component is separated from a second component of the processing chamber by a thermal break.

9. The substrate processing system of claim 1, wherein the top or cool plate includes a plurality of gas zones.

10. The substrate processing system of claim 1, wherein the cooling loop includes a quick-disconnect connection.

11. The substrate processing system of claim 1, further comprising a process cooling water (PCW) cooling loop.

12. The substrate processing system of claim 11, wherein the dual-phase cooling loop can exchange heat with the PCW cooling loop.

13. The substrate processing system of claim 1, wherein the top plate or cool plate is included in a stack assembly.

14. The substrate processing system of claim 1, wherein the one or more passageways of the top plate or the cool plate include a full or partial concentric ring pattern.

15. A method of regulating processing temperature in a substrate processing system comprising a processing chamber or a component thereof, the method comprising:
providing a dual-phase cooling system for regulating a temperature of the processing chamber or a component thereof, the dual-phase cooling system including a cooling loop in thermal communication with the processing chamber or the component;
the processing chamber or the component including a top plate or a cool plate comprising one or more passageways forming part of the cooling loop and through which the dual-phase coolant can pass in a path to and from a heat exchanger;
passing a dual-phase coolant through the cooling loop to and from the heat exchanger; and
operating a back-pressure regulator for regulating a pressure of the dual-phase coolant.
